(19) United States
(12) Patent Application Publication
(10) Pub. No.: US 2010/0206619 A1
(43) Pub. Date: Aug. 19, 2010

(54) PACKAGE SUBSTRATE STRUCUTRE WITH CAVITY AND METHOD FOR MAKING THE SAME

(76) Inventors: Kuo-Ching Chen, Changhua City (TW); Tsung-Yuan Chen, Taoyuan County (TW); Cheng-Pin Chien, Shulin City (TW)

Correspondence Address: NORTH AMERICA INTELLECTUAL PROPERTY CORPORATION, P.O. BOX 506, MERRIFIELD, VA, 22116, US

(21) Appl. No.: 12/485,889

(22) Filed: Jun. 16, 2009

(30) Foreign Application Priority Data
Feb. 16, 2009 (TW) 098104814

(51) Int. Cl. H05K 1/00; H05K 1/16; H05K 1/11; H05K 3/30

(52) U.S. Cl. 174/252; 174/260; 174/262; 29/832

(57) ABSTRACT

A package substrate structure includes a substrate with a first side and a second side opposite to the first side, a via connecting the first side and the second side, a cavity in the substrate and on the first side, and a patterned conductive layer disposed on at least one of the first side and the second side, filling the cavity and the via, and including a first conductive layer, a second conductive layer and a third conductive layer. The second conductive layer is different from at least one of the first conductive layer and the third conductive layer.

### BACKGROUND OF THE INVENTION

1. Field of the Invention

The present invention relates to a package substrate structure and a method for making the same. In particular, the present invention relates to a package substrate structure with a cavity and a method for making the same.

2. Description of the Prior Art

A circuit board is considered as the core element of an electronic device. In order to achieve a particular function, a functional chip or an integrated circuit is packaged with a substrate to obtain a circuit board of a package. There are many conventional methods for packaging. For example, in a method called “flip chip,” the chip is flipped over to be electrically connected to the connecting points of a substrate through solder balls.

Such method not only reduces the electronic communicating path between the chip and the substrate in the product to be suitable for the high speed elements, but it is also very popular since it greatly reduces the size of dices. With the growing demands of the cheaper, smaller and faster portable and multi-function electronic devices, the high density packaging standard for the flip chip is higher and higher.

Besides, because the conductive wires in the circuit board have their own thickness, the embedded circuit structure therefore draws more attention than ever to pursue a thinner product, to meet the demands of finer wires and to overcome the drawbacks of the etching procedure. Because the wire pattern is embedded in the substrate, the thickness of the wires seems omitted to further reduce the thickness of the products after packaging.

The traditional single circuit packaging element using single chip packaging by massive build-up layers can no longer meet the demands of the multi-function elements for use in smaller and lighter electronic products.

Further, the problem to dissipate excess heat from the massive heat source, the integrated circuits for example, is getting more and more difficult with the increasing efficiency of the integrated circuits. If the waste heat cannot be dissipated in time from the massive heat source, the expected heat shock will do a lot of damages to the package substrate.

First, how to use the space in a substrate better and second, how to dissipate heat from the massive heat source more efficiently become major problems in this field.

### SUMMARY OF THE INVENTION

The present invention therefore proposes a package substrate structure with a cavity and a method for making the same to provide a solution for the highly integrated circuit. A composite material is used for the heat-dissipating of the highly integrated circuit elements.

The present invention first proposes a package substrate structure with a cavity. The package substrate structure with a cavity of the present invention includes a substrate with a first side and a second side opposite to the first side; a via for connecting the first side and the second side; a cavity disposed in the substrate and on the first side; and a patterned conductive material layer disposed on at least one of the first side and the second side. The patterned conductive material layer includes a first conductive material layer, a second conductive material layer and a third conductive material layer in order. The second conductive material layer is different from at least one of the first conductive material layer and the third conductive material layer.

The present invention again proposes a method for forming a package substrate structure. First, a conductive material layer including a first conductive material layer, a second conductive material layer and a third conductive material layer in order is provided. Second, the first conductive material layer is patterned to form a first conductive material region and to expose the second conductive material layer. Then, the second conductive material layer is covered with a dielectric layer. Later, the dielectric layer and the first conductive material region are covered with a first conductive material Afterwards, a via is formed to connect the first conductive material, the dielectric layer, the second conductive material layer and the third conductive material layer. To be continued, the via is filled with the first conductive material and to electrically connect the first conductive material and the third conductive material layer. Thereafter, the first conductive material, the second conductive material layer and the third conductive material layer are patterned to expose the dielectric layer so as to form the package substrate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate various examples of the package substrate structure with a cavity of the present invention.

FIGS. 2A and 2B illustrate examples of the cavity which accommodates an electronic element of the package substrate structure of the present invention.

FIGS. 3A, 3B and 3C illustrate various examples of the cavity as a heat sink of the package substrate structure of the present invention.

FIGS. 4-15 illustrate various examples of the method for forming a package substrate structure of the present invention, wherein FIGS. 10A to 15B illustrate a first example of the method for forming a package substrate structure of the present invention, FIGS. 10B to 15B illustrate a second example of the method for forming a package substrate structure of the present invention, and FIGS. 10C and 3C illustrate a third example of the method for forming a package substrate structure of the present invention.

### DETAILED DESCRIPTION

The present invention provides a package substrate structure with a cavity and a method for making the same. On one aspect, the package substrate structure with a cavity of the present invention uses the space in the package substrate well to integrate the high density integrated circuit element. On another aspect, in the package substrate structure of the present invention a composite material is used for the heat-dissipating of the highly integrated circuit elements.

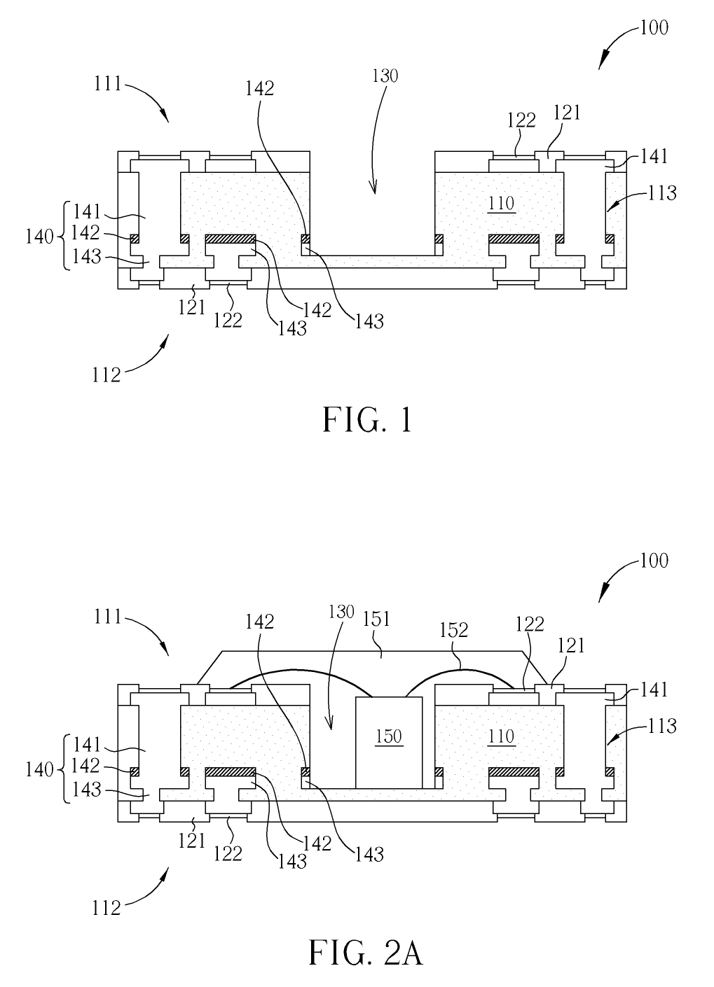

The present invention first provides a package substrate structure with a cavity. FIGS. 1-3 illustrate various examples of the package substrate structure with a cavity of the present invention. Please refer to FIG. 1, the package substrate structure 100 with a cavity of the present invention includes a substrate 110, a via 113, a cavity 130, a patterned conductive layer 140, a patterned conductive wire layer 160 and an optional solder mask layer 121 and an optional anti-oxidation layer 122. The substrate 110 has a first side 111 and a second side 112 opposite to the first side 111. The substrate 110 may be a dielectric material, for example a glass fiber prepreg. The patterned conductive wire layer 160 may be an embedded wire structure of copper.

The via 113 is disposed in the substrate 110 and usually includes a conductive material for connecting the first side 111 and the second side 112. The size of the via 113 is optional. The cavity 130 is disposed in the substrate 110, too, on the first side 111 or on the second side 112, and exposed by the first side 111 or exposed by the second side 112.

The patterned conductive material layer 140 is disposed on at least one of the first side 111 and the second side 112, and in the via 113 and in the cavity 130. For example, the patterned conductive material layer 140 fills the via 113 and electrically connects the first side 111 and the second side 112. The patterned conductive material layer 140 may be a composite material layer or a multi-layer conductive structure. For example, the patterned conductive material layer 140 may include a first conductive material layer 141, a second conductive material layer 142 and a third conductive material layer 143. In other words, there may be other conductive material layer(s) on the first conductive material layer 141 and on the third conductive material layer 143. The solder mask layer 121 and the anti-oxidation layer 122 are optionally disposed on the patterned conductive material layer 140.

The second conductive material layer 142 should be different from at least one of the first conductive material layer 141 and the third conductive material layer 143. For example, the first conductive material layer 141 may be made of Al or Cu, the second conductive material layer 142 may be made of Ni or Al and the third conductive material layer 143 maybe made of Al or Cu. Alternatively, the second conductive material layer 142 is different from both the first conductive material layer 141 and from the third conductive material layer 143. Besides, the first conductive material layer 141 and the third conductive material layer 143 may be the same or mutually different.

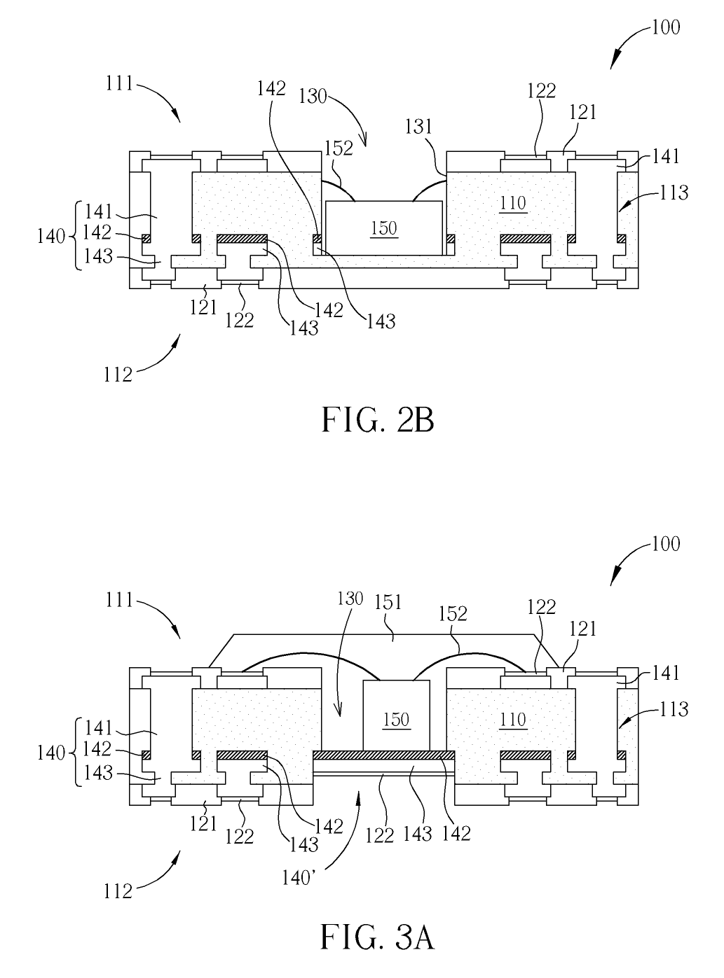

FIGS. 2A and 2B illustrate examples of the cavity which accommodates an electronic element of the package substrate structure of the present invention. Please refer to FIG. 2A. in one example of the present invention, if the cavity 130 is used to accommodate an electronic element 150, an integrated circuit, a die, an active element, or a passive element for example, the size of the cavity 130 may go with the size of the electronic element 150 or slightly larger. If the cavity 130 is slightly larger than the electronic element 150, a filler 151 may optionally fill the gap between the cavity 130 and the electronic element 150. Or, the filler 151 as a sealant seals the cavity 130 and the electronic element 150. The filler 151 may be an electrically insulating material, such as ceramics, epoxy resins, modified epoxy resins, polyesters, acrylate, fluoro-containing polymer, (PPO) polyphenylene oxide, polyimide, phenolic resins, polysulfone (PSF), Si-containing polymer, BT resins, polycyanate, polyethylene or a combination thereof. In one embodiment, the electronic device 150 may be electrically connected to the first side 111, for example the first conductive material layer 141 on the first side 111 or other conductive material layer(s) through a wire bond 152. In another embodiment, the electronic device 150 may also be electrically connected to an inner wall 131 of the cavity 130 or the first side 111 through a wire bond 152.

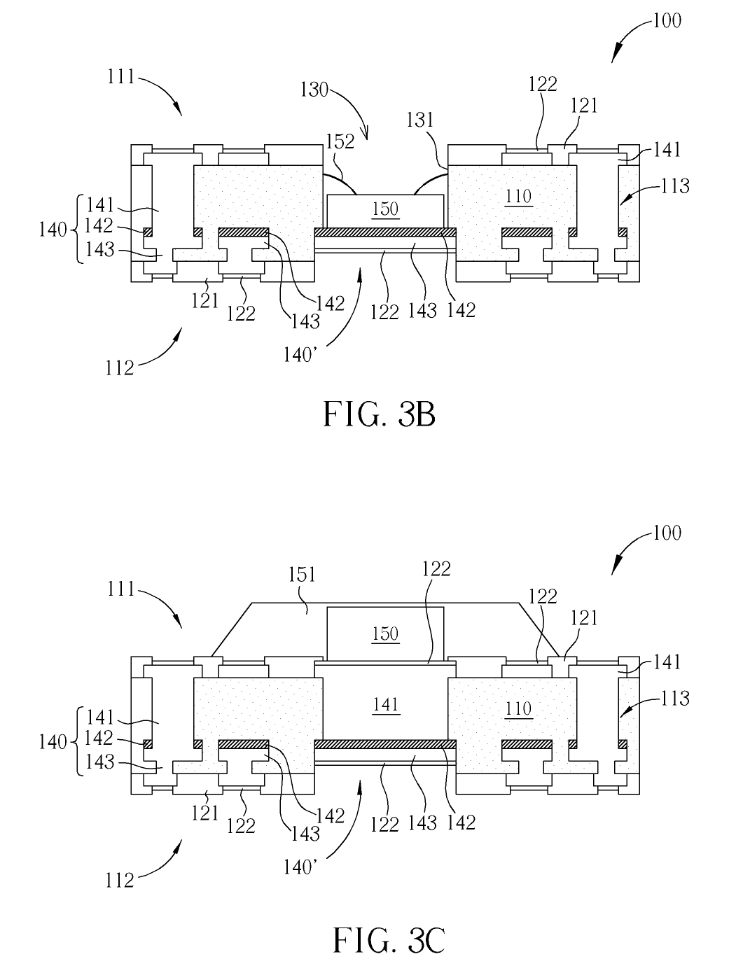

FIGS. 3A, 3B and 3C illustrate examples of the cavity as a heat sink of the package substrate structure of the present invention Please refer to FIG. 3A, in another example of the present invention, the package substrate structure 100 has a heat sink structure 140′. The electronic device 150 is disposed in the cavity 130 so that the waste heat generated by the electronic device 150 is dissipated by the heat sink structure 140′ on the second side 112. Optionally, the filler 151 may also be used to seal and to fixate the electronic element 150. In one embodiment, the electronic device 150 maybe electrically connected to the first side 111, for example the first conductive material layer 141 on the first side 111 or other conductive material layer(s) through a wire bond 152. Or, in another embodiment, the electronic device 150 may also be electrically connected to another conductive material layer of an inner wall 131 of the cavity 130 or the first side 111 through a wire bond 152.

In still another example, as shown in FIG. 3C, the electronic element 150 may be disposed on the first conductive material layer 141, Cu for example, filling the cavity 130 and on the optional anti-oxidation layer 122, Ni/Au alloy for example. In this example, the patterned conductive layer 140 is disposed on the bottom of the cavity 130 and exposes the second side 112 to form a heat sink structure 140′. The waste heat generated by the electronic device 150 is then dissipated through the first conductive material layer 141 by the heat sink structure 140′ on the second side 112. Optionally, the electronic device 150 may be electrically connected to the first side 111, for example the first conductive material layer 141 on the first side 111 or other conductive material layer(s). Or, in another embodiment, the filler 151 may also be used to seal the electronic element 150.

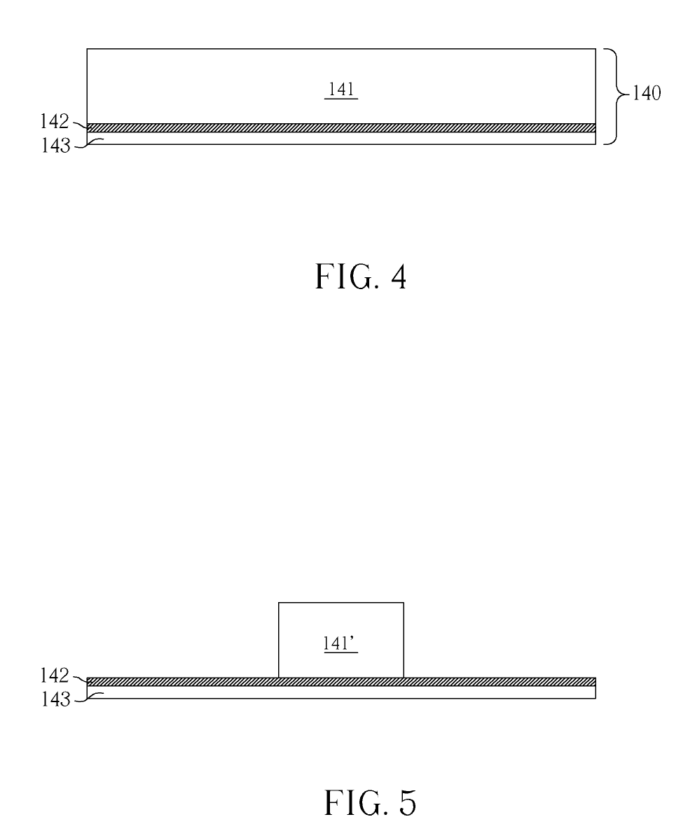

The present invention also provides a method for forming a package substrate structure. FIGS. 4-15 illustrate various examples of the method for forming a package substrate structure of the present invention. First, please refer to FIG. 4, a conductive material layer 140 is provided. The conductive material layer 140 may be a composite material layer, for example, the conductive material layer 140 may include a first conductive material layer 141, a second conductive material layer 142 and a third conductive material layer 143. However, the second conductive material layer 142 should be different from at least one of the first conductive material layer 141 and the third conductive material layer 143. For example, the first conductive material layer 141 may be made of Al or Cu, the second conductive material layer 142 may be made of Ni or Al and the third conductive material layer 143 may be made of Al or Cu. Alternatively, the second conductive material layer 142 is different from both the first conductive material layer 141 and from the third conductive material layer 143. Besides, the first conductive material layer 141 and the third conductive material layer 143 may be the same or mutually different.

Second, as shown in FIG. 5, the first conductive material layer 141 is patterned by using the second conductive material layer 142 as an etching stop layer to form a first conductive material region 141′ (including the patterned first conductive material layer 141) and to expose the second conductive material layer 142. For example, a first conductive material region 141′ of 0.5 mm×0.5 mm to 10 mm×10 mm can be formed by an etching process such as wet etching process.

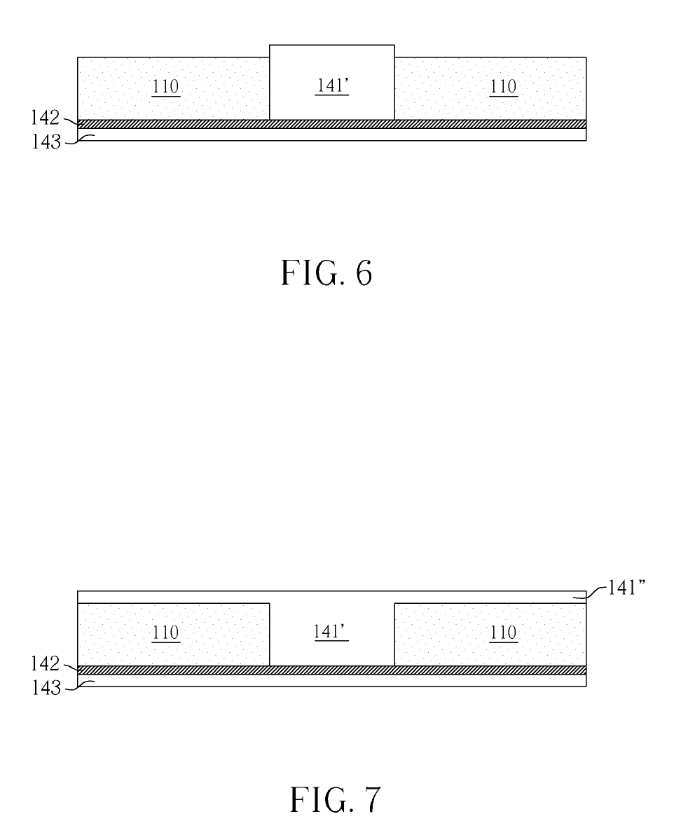

Then, as shown in FIG. 6, a dielectric layer 110 is used to cover the second conductive material layer 142 and to surround the first conductive material region 141′. Or, an opening (not shown) may be first formed in the dielectric layer 110. The size or the location of the opening may be in accordance with the size or the location of the first conductive material region 141′. The two then are pressed. In other words, the first conductive material region 141′ may be regarded as being pressed into the dielectric layer 110 (opening) The dielectric layer 110 may be a soft insulating material, such as a prepreg or an insulating resin layer.

Later, as shown in FIG. 7, another conductive material 141″ is used to cover the dielectric layer 110 and the patterned first conductive material layer 141 in the first conductive material region 141′. For example, a copper foil may be used to cover both the dielectric layer 110 and the first conductive material region 141′.

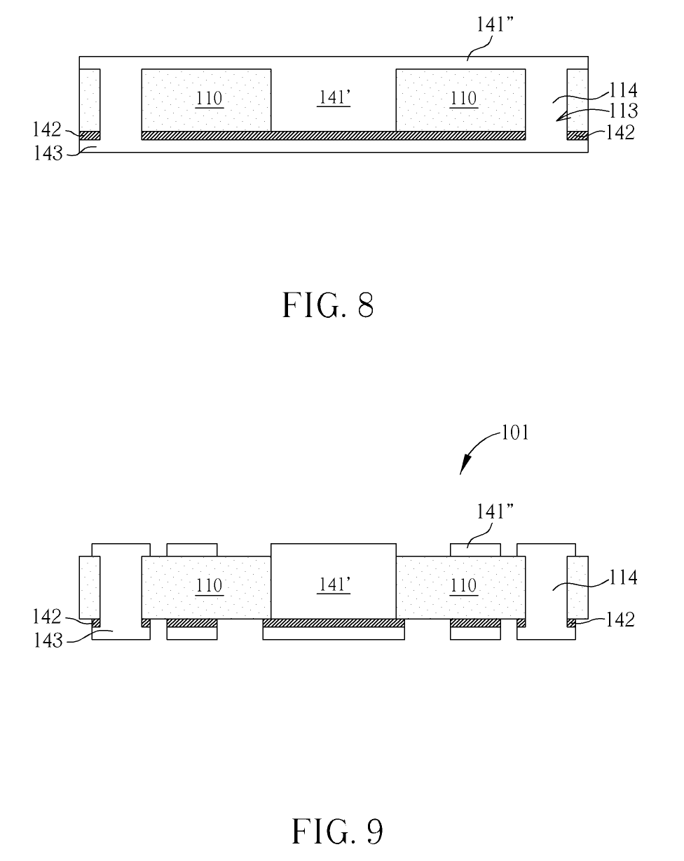

Afterwards, as shown in FIG. 8, a via 113 is formed to penetrate the conductive material 141″, the dielectric layer 110, the second conductive material layer 142 and the third conductive material layer 143. To be continued, a conductive material is electroplated to fill the via 113 to form a conductive channel 114 to electrically connect the conductive material 141″ and the third conductive material layer 143.

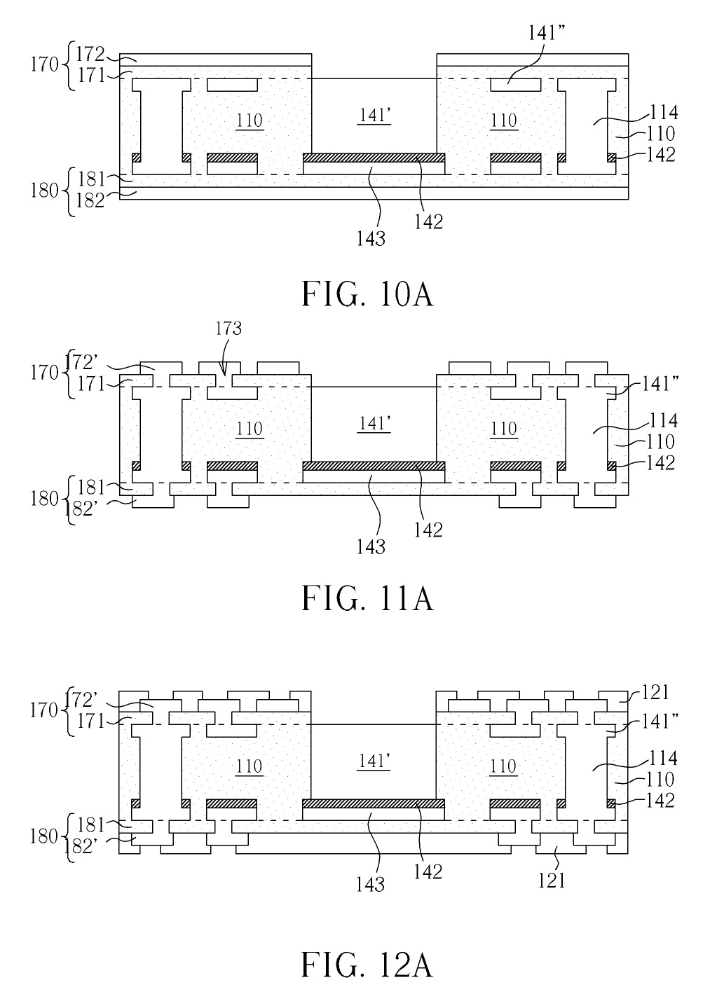

Thereafter, as shown in FIG. 9, the conductive material 141″, the second conductive material layer 142 and the third conductive material layer 143 are patterned, such as by a lithographic and an etching process, to expose part of the dielectric layer 110 so as to form the package substrate structure 101. The obtained package substrate structure 101 may be further modified to form various examples, which will be detailed as follows.

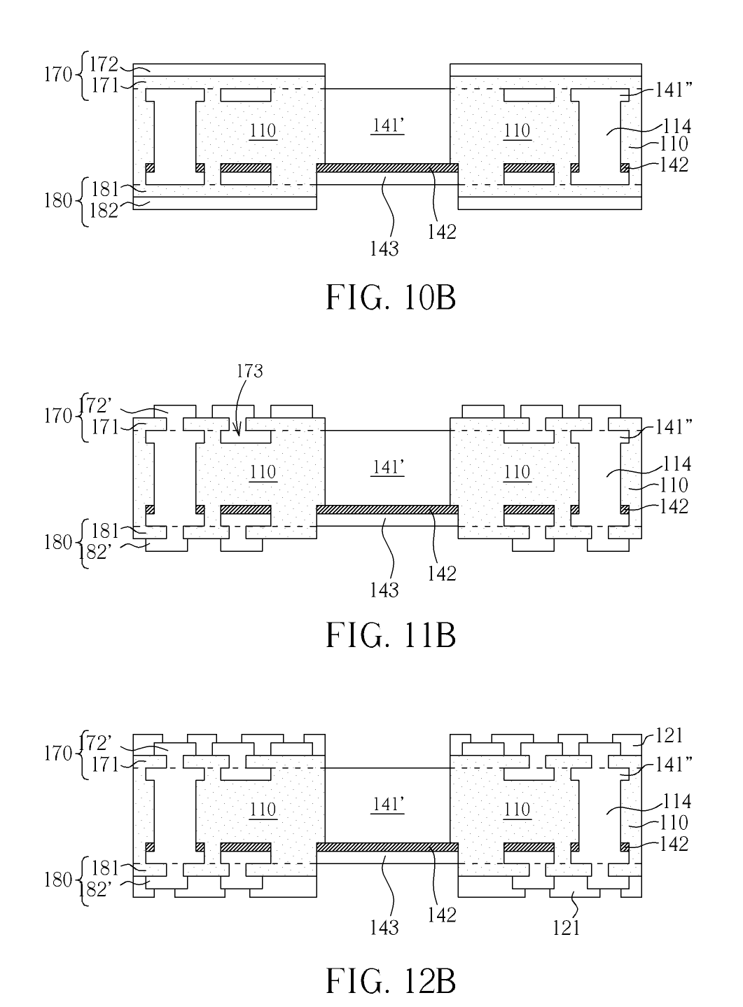

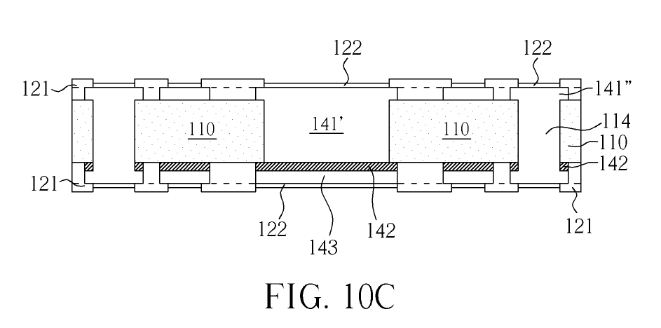

In a first example of the method for forming a package substrate structure of the present invention, as shown in FIG. 10A, a build-up lamination process is carried out. First, a first build-up layer 170 and a second build-up layer 180 are used to cover the package substrate structure 101. The first build-up layer 170 includes a first build-up insulating layer 171 and a first build-up conductive material layer 172. The second build-up layer 180 includes a second build-up insulating layer 181 and a second build-up conductive material layer 182. The build-up insulating layers may be made of a dielectric material, such as this of the dielectric layer 110. The build-up conductive material layers may be a copper foil. An opening may be formed in advance the first build-up insulating layer 171 and the first build-up conductive material layer 172 which cover the conductive material 141″ to expose the first conductive material region 141′. In addition, the second build-up layer 180 covers the patterned second conductive material layer 142 and the patterned third conductive material layer 143.

Second, as shown in FIG. 11A, the first build-up conductive material layer 172 and the second build-up conductive material layer 182 are patterned to form a pre-determined outer wire pattern, i.e. the first build-up conductive wire layer 172′ and the second build-up conductive wire layer 182′. Further, a through hole 173 is formed by a process such as laser drilling for electric connection. Subsequently, the conductive material 141″, the second conductive material layer 142, the third conductive material layer 143 and the outer first build-up conductive wire layer 172′ and the second build-up conductive wire layer 182′ together form an electric connection network through the conductive channel 114.

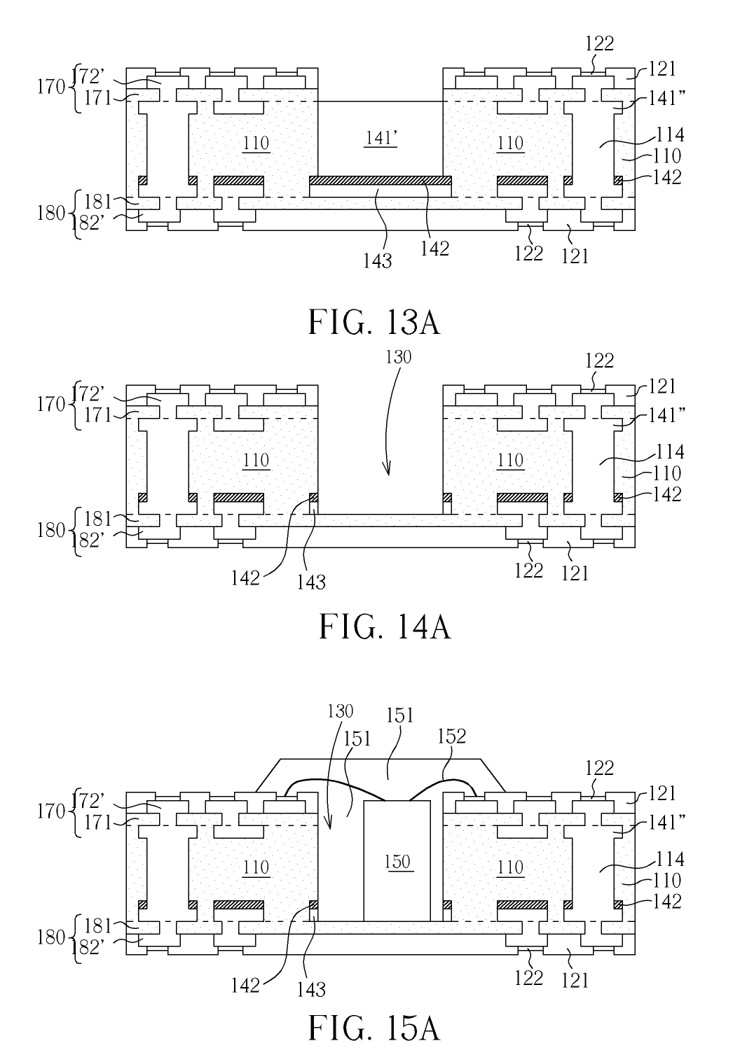

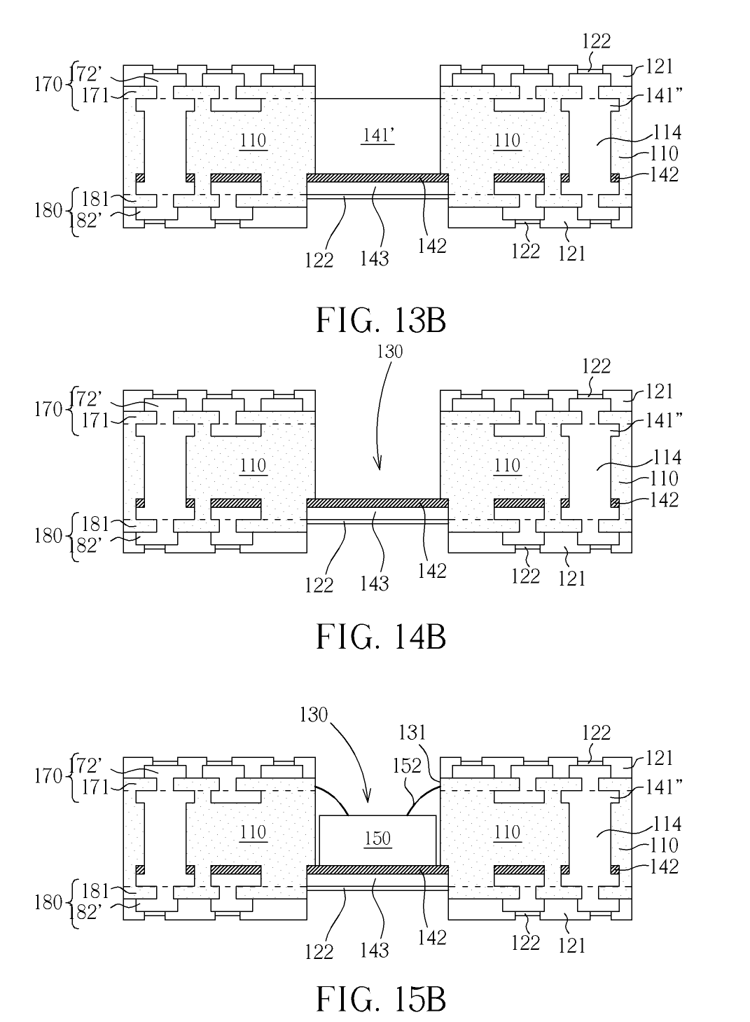

Afterwards, as shown in FIG. 12A, optionally a solder mask layer 121 selectively covers the first build-up conductive wire layer 172′ and the second build-up conductive wire layer 182′, and/or, as shown in FIG. 13A, an anti-oxidation layer 122 as a protection layer selectively covers the first build-up conductive wire layer 172′ and the second build-up conductive wire layer 182′. The anti-oxidation layer 122 may include Sn, Sn alloy, Ag, Ni, Au or Ni/Au composite layer.

Then, as shown in FIG. 14A, an etching procedure is performed to roughly remove the first conductive material layer in the first conductive material region 141′, the patterned second conductive material layer 142 and the patterned third conductive material layer 143 to form a cavity 130. In other words, the etching procedure generally removes the conductive material which is not protected by the anti-oxidation layer 122 but possibly some of the patterned second conductive material layer 142 and the patterned third conductive material layer 143 are still left behind. The package substrate structure 101 now becomes a package substrate structure with the cavity 130. The etching procedure may be a conventional etching procedure.

Later, as shown in FIG. 15A/15B, an electronic device 150, such as an integrated circuit, is disposed in the cavity 130. Please refer to FIG. 15A, in one embodiment of the present invention, the size of the cavity 130 may go with the size of the electronic element 150 or slightly larger. If the cavity 130 is slightly larger than the electronic element 150, a filler 151 may optionally fill the gap between the cavity 130 and the electronic element 150. Or, the filler 151 as a sealant seals the cavity 130 and the electronic element 150. The filler 151 may be an electrically insulating material, such as ceramics, epoxy resins, modified epoxy resins, polyesters, acrylate, fluoro-containing polymer, (PPO) polyphenylene oxide, polyimide, phenolic resins, polysulfone (PSF), Si-containing polymer, BT resins, polycyanate, polyethylene or a combination thereof. In this embodiment, the electronic device 150 may be electrically connected to the first side 111, for example the first build-up conductive wire layer 172′ on the first side 111 or other conductive material layer(s) through a wire bond 152. In another embodiment, the electronic device 150 may also be electrically connected to a conductive material layer of an inner wall 131 of the cavity 130 through a wire bond 152, as shown in FIG. 15B.

In a second example of the method for forming a package substrate structure of the present invention, as shown in FIG. 10B, a build-up lamination process is carried out. Different from what is disclosed in the first example of the present invention, both the first build-up layer 170 and the second build-up layer 180 have a reserved opening so that the second build-up layer 180 indirectly exposes the first conductive material region 141′, to form a heat sink structure 140′ composed of the patterned second conductive material layer 142 and the patterned third conductive material layer 143.

Second, as shown in FIG. 11B, the first build-up conductive material layer 172 and the second build-up conductive material layer 182 are patterned to form a pre-determined outer wire pattern, i.e. the first build-up conductive wire layer 172′ and the second build-up conductive wire layer 182′. Further, a through hole 173 is formed by a process such as laser drilling for electric connection. Subsequently, the patterned conductive material 141″, the patterned second conductive material layer 142, the patterned third conductive material layer 143 and the outer first build-up conductive wire layer 172′ and the second build-up conductive wire layer 182′ together form an electric connection network through the conductive channel 114.

Afterwards, as shown in FIG. 12B, optionally a solder mask layer 121 selectively covers the first build-up conductive wire layer 172′ and the second build-up conductive wire layer 182′, and/or, as shown in FIG. 13B, an anti-oxidation layer 122 as a protection layer selectively covers the first build-up conductive wire layer 172′ and the second build-up conductive wire layer 182′. The anti-oxidation layer 122 may include Sn, Sn alloy, Ag, Ni, Au or Ni/Au composite layer.

Then, as shown in FIG. 14B, an etching procedure is performed using the patterned second conductive material layer 142 as an etching-stop layer to remove the remaining first conductive material layer in the first conductive material region 141′, to form a cavity 130. The package substrate structure 101 now becomes a package substrate structure with both the cavity 130 and the heat sink structure 140′. The etching procedure may be a conventional etching procedure.

Later, as shown in FIG. 3A/15B, an electronic device 150 is disposed in the cavity 130. Please refer to FIG. 3A, in one embodiment of the present invention, a filler 151 may optionally fill the gap between the cavity 130 and the electronic element 150. Or, the filler 151 as a sealant seals the cavity 130 and the electronic element 150. In this embodiment, the electronic device 150 may be electrically connected to the first side 111, for example the first build-up conductive wire layer 172′ on the first side 111 or other conductive material layer(s) through a wire bond 152. In another embodiment, the electronic device 150 may also be electrically connected to other conductive material layer of an inner wall 131 of the cavity 130 through a wire bond 152, as shown in FIG. 15B.

FIG. 10C illustrates a third example of the method for forming a package substrate structure of the present invention. Different from what is disclosed in the first example and in the second example of the present invention, no build-up lamination process and no etching process is carried out. Rather, a solder mask layer 121 and/or an anti-oxidation layer 122 as a protection layer selectively cover the dielectric layer 110, the patterned conductive material 141″ and the patterned third conductive material layer 143 and at the same time the first conductive material layer in the first conductive material region 141′ remains. The solder mask layer 121 does not cover the heat sink structure 140′ composed of the patterned second conductive material layer 142 and the patterned third conductive material layer 143.

As shown in FIG. 3C, an electronic element 150 is disposed on the first conductive material layer in the first conductive material region 141′, or on the optional anti-oxidation layer 122. In this example, the patterned conductive layer 140 is disposed on the bottom of the cavity 130 and exposes the second side 112 to form a heat sink structure 140′. The waste heat generated by the electronic device 150 is then dissipated through the first conductive material layer 141 by the heat sink structure 140′ on the second side 112. Optionally, the electronic device 150 may be electrically connected to the first side 111, for example the first conductive material layer 141 on the first side 111 or other conductive material layer(s) and/or, a sealant 151 may also be used to seal and to fixate the electronic element 150.

Those skilled in the art will readily observe that numerous modifications and alterations of the device and method may be made while retaining the teachings of the invention.

What is claimed is:

1. A package substrate structure with a cavity, comprising:
a substrate with a first side and a second side opposite to said first side;
a via for connecting said first side and said second side;
said cavity disposed in said substrate and on said first side; and
a patterned conductive material layer disposed on at least one of said first side and said second side, filling said cavity and said via, and comprising a first conductive material layer, a second conductive material layer and a third conductive material layer in order, wherein said second conductive material layer is different from at least one of said first conductive material layer and said third conductive material layer.

2. The package substrate structure with a cavity of claim 1, wherein said second conductive material layer is different from said first conductive material layer and from said third conductive material layer.

3. The package substrate structure with a cavity of claim 1, wherein said first conductive material layer and said third conductive material layer are different.

4. The package substrate structure with a cavity of claim 1, wherein said first conductive material layer and said third conductive material layer are the same.

5. The package substrate structure with a cavity of claim 1, wherein said patterned conductive material layer is disposed on the bottom of said cavity and exposing said second side to form a heat sink structure.

6. The package substrate structure with a cavity of claim 1, wherein said second conductive material layer is selected form a group consisting of Al and Ni.

7. The package substrate structure with a cavity of claim 1, further comprising:
an electronic device disposed in said cavity.

8. The package substrate structure with a cavity of claim 7, wherein said electronic device is electrically connected to at least one of an inner wall of said cavity and said first side through a wire bond.

9. A method for forming a package substrate structure, comprising:
providing a conductive material layer comprising a first conductive material layer, a second conductive material layer and a third conductive material layer in order;
patterning said first conductive material layer to form a first conductive material region and to expose said second conductive material layer;
covering said second conductive material layer with a dielectric layer;
covering said dielectric layer and said first conductive material region with a first conductive material;
forming a via to connect said first conductive material, said dielectric layer, said second conductive material layer and said third conductive material layer;
filling said via with said first conductive material and to electrically connect said first conductive material and said third conductive material layer; and
patterning said first conductive material, said second conductive material layer and said third conductive material layer to expose said dielectric layer so as to form said package substrate structure.

10. The method of claim 9, further comprising:
covering said patterned first conductive material with a first build-up layer to expose said first conductive material region and covering said patterned second conductive material layer and said patterned third conductive material layer with a second build-up layer, wherein said first build-up layer comprises a first build-up insulating layer and a first build-up conductive material layer and said second build-up layer comprises a second build-up insulating layer and a second build-up conductive material layer.

11. The method of claim 10, further comprising:
patterning said first build-up conductive material layer and said second build-up conductive material layer.

12. The method of claim 10, wherein said second build-up layer indirectly exposes said first conductive material region to form a heat sink structure.

13. The method of claim 12, further comprising:
patterning said first build-up conductive material layer and said second build-up conductive material layer.

14. The method of claim 13, further comprising:
performing an etching procedure to remove said first conductive material layer in said first conductive material region to form a cavity.

15. The method of claim 9, further comprising:
selectively covering said dielectric layer, said patterned first conductive material layer and said patterned third conductive material layer with a solder mask layer.

16. The method of claim 13, further comprising:
selectively covering said patterned first conductive material layer and said patterned third conductive material layer with an anti-oxidation layer.

17. The method of claim 9, further comprising:
disposing an electronic device on said first conductive material region.
